(19) United States
(12) Patent Application Publication
(10) Pub. No.: US 2026/0143721 A1
(43) Pub. Date: May 21, 2026

(54) ELECTRO-OPTIC PHOTONIC MEMORY DEVICE WITH AN INTEGRATED FERROELECTRIC FIELD EFFECT TRANSISTOR

(71) Applicant: National University of Singapore, Singapore (SG)

(72) Inventors: Zefeng XU, Singapore (SG); Chun-Kuei CHEN, Singapore (SG); Aaron Voon-Yew Thean, Singapore (SG)

(21) Appl. No.: 19/389,441

(22) Filed: Nov. 14, 2025

(30) Foreign Application Priority Data
Nov. 19, 2024 (SG) 10202403607W

(51) Int. Cl. H10B 69/00; G02B 6/12; H10D 30/01; H10D 30/69; H10D 62/80; H10D 64/01; H10D 64/68

(52) U.S. Cl. CPC H10B 69/00; G02B 6/12004; H10D 30/0415; H10D 30/701; H10D 62/875; H10D 64/033; H10D 64/689

(57) ABSTRACT

This document describes an electro-optic photonic memory device comprising a micro-ring resonator, and at least one ferroelectric field effect transistor (FeFET) that is disposed along a partial circumference of a raised ring waveguide of the micro-ring resonator. The FeFET comprises a ferroelectric gate stack and a heterojunction channel layer.

### CROSS-REFERENCE TO RELATED APPLICATION

This application claims the benefit of priority to Singapore patent application 10/202403607W which was filed on 19 Nov. 2024, the contents of which are hereby incorporated by reference in its entirety for all purposes.

### TECHNICAL FIELD

This application relates to an electro-optic photonic memory device comprising a micro-ring resonator, and at least one ferroelectric field effect transistor that is disposed along a partial circumference of a raised ring waveguide of the micro-ring resonator.

### BACKGROUND

Emerging technologies such as photonic neural networks, quantum photonic computing, optical sensing, and high-speed communication systems require efficient data transfer between memory and photonic components. Specifically, these technologies rely on the rapid exchange and processing of data within photonic circuits, where light is used not only for signal propagation but also for computation and storage. However, as the scale and complexity of such systems increase, achieving seamless integration between memory and photonic platforms presents a major challenge commonly referred to as the “memory wall.” This bottleneck arises when data movement between the photonic processing units and conventional electronic memory becomes increasingly energy-intensive and latency-limited. Those skilled in the art face the issue that each optical-to-electrical and electrical-to-optical conversion step introduces energy overhead, signal degradation, and timing mismatch, resulting in reduced system efficiency and bandwidth. These limitations are particularly detrimental in memory photonic computing architectures, where frequent data access is required to perform optical matrix operations, neural network weight updates, or quantum state manipulations.

A main obstacle faced by those skilled in the art lies in achieving strong and efficient electro-optic coupling between the electrical memory element and the propagating optical modes within a photonic waveguide. The electro-optic interaction must be sufficiently strong to modulate the refractive index or phase of light with minimal electrical energy. However, most existing photonic memory technologies fall short of this requirement. For example, reported phase-change materials (PCM) rely on thermally induced structural transitions between amorphous and crystalline phases to modulate optical properties. While they offer non-volatility, their operation requires high switching energy (in the range of picojoules to nanojoules per bit) and repeated heating cycles that degrade material endurance. Floating-gate and memristor-based photonic memories offer electrical tunability but exhibit poor optical confinement and weak modulation depth due to their limited electro-optic coefficients and interface losses. Ferroelectric thin-film systems, although capable of polarization-based non-volatility, often suffer from inefficient coupling between ferroelectric polarization and optical modes, leading to low refractive index tunability and unstable retention under continuous illumination. Furthermore, many of these solutions are thermally driven or require high-voltage operation, making them incompatible with low-power, high-speed integrated photonic circuits.

As such, those skilled in the art are constantly looking for solutions to overcome the limitations of existing photonic memory devices by achieving stronger electro-optic coupling, lower switching energy, and improved non-volatile retention. In particular, there is a need for a memory element that can efficiently convert and store electrical states into optical responses within a photonic waveguide without relying on thermal effects or high-voltage operation.

### SUMMARY

In one aspect, the present disclosure describes an electro-optic photonic memory device comprising a micro-ring resonator including a raised ring waveguide formed on a substrate, wherein the raised ring waveguide comprises a non-centrosymmetric material. The device also includes a ferroelectric field effect transistor (FeFET) disposed along a partial circumference of the raised ring waveguide of the micro-ring resonator, the FeFET comprising a channel layer disposed on the raised ring waveguide such that the channel layer extends over a top surface of the raised ring waveguide, over an inner portion of the substrate disposed inward of the raised ring waveguide, and over an outer region of the substrate disposed outward of the raised ring waveguide. The FeFET also has an interfacial layer disposed on the channel layer and a first electrode layer disposed on the interfacial layer such that the first electrode layer overlies the channel layer formed on the inner portion of the substrate. The FeFET further includes a second electrode layer disposed on the interfacial layer such that the second electrode overlies the channel layer formed on the outer portion of the substrate, a ferroelectric layer disposed on the interfacial layer such that the ferroelectric layer overlies the channel layer formed on the top surface of the raised ring waveguide, and a gate electrode disposed on the ferroelectric layer. It should be noted that a polarization state of the ferroelectric layer changes in response to a bias voltage being applied to the gate electrode and the first and second electrode layers being electrically grounded, the change in the polarization state of the ferroelectric layer causing the generation of a resultant electric field that extends from the ferroelectric layer into raised ring waveguide to modulate a refractive index of the non-centrosymmetric material.

According to an embodiment of the one aspect, the bias voltage may comprise a positive voltage that causes ferroelectric dipoles of the ferroelectric layer to align in a direction opposite to a spontaneous polarization of the non-centrosymmetric material, causing the resultant electric field to extend in a downward direction from the ferroelectric layer into the raised ring waveguide.

According to an embodiment of the one aspect, upon removal of the positive voltage, the ferroelectric layer partially depolarizes due to the resultant electric field extending in an upward direction from the raised ring waveguide to the ferroelectric layer, the resultant electric field reducing a magnitude of remanent polarization of the ferroelectric layer while maintaining a same polarization direction.

According to an embodiment of the one aspect, the bias voltage may comprise a negative voltage that causes ferroelectric dipoles of the ferroelectric layer to align in a direction aligned with a spontaneous polarization of the non-centrosymmetric material, causing the resultant electric field to extend in an upward direction from the raised ring waveguide to the ferroelectric layer.

According to an embodiment of the one aspect, a stored memory state of the photonic memory device may be determined by optically interrogating a resonance wavelength of the micro-ring resonator using an input optical signal coupled into the raised ring waveguide.

According to an embodiment of the one aspect, a stored memory state of the photonic memory device may be determined by measuring a channel current through the channel layer in response to a source-drain voltage applied between the first and second electrode layers, the channel current being modulated by the polarization state of the ferroelectric layer.

According to an embodiment of the one aspect, the non-centrosymmetric material may comprise Lithium Niobate, Potassium Dihydrogen Phosphate, Gallium Arsenide or Barium Titanate, the ferroelectric layer may comprise Hafnium Zirconium Oxide, Barium Titanate, or Lead Zirconate Titanate, the channel layer may comprise Indium Gallium Zinc Oxide and the interfacial layer may comprise Indium Tin Oxide.

According to an embodiment of the one aspect, a plurality of the FeFETs may be disposed along different circumferential sections of the raised ring waveguide, wherein each of the plurality of FeFETs is independently addressable by applying a corresponding bias voltage to the gate electrode of the FeFET to cumulatively modulate the refractive index of the non-centrosymmetric material.

In another aspect, the present disclosure describes a method for forming an electro-optic photonic memory device. The method comprises the steps of forming a micro-ring resonator including a raised ring waveguide formed on a substrate, wherein the raised ring waveguide comprises a non-centrosymmetric material and forming a ferroelectric field effect transistor (FeFET) along a partial circumference of the raised ring waveguide of the micro-ring resonator. The forming of the FeFET comprises the steps of forming a channel layer on the raised ring waveguide such that the channel layer extends over a top surface of the raised ring waveguide, over an inner portion of the substrate disposed inward of the raised ring waveguide, and over an outer region of the substrate disposed outward of the raised ring waveguide; forming an interfacial layer on the channel layer; forming a first electrode layer on the interfacial layer such that the first electrode layer overlies the channel layer formed on the inner portion of the substrate; forming a second electrode layer on the interfacial layer such that the second electrode layer overlies the channel layer formed on the outer portion of the substrate; forming a ferroelectric layer on the interfacial layer such that the ferroelectric layer overlies the channel layer formed on the top surface of the raised ring waveguide; and forming a gate electrode on the ferroelectric layer. A polarization state of the ferroelectric layer may be changed by applying a bias voltage to the gate electrode and electrically grounding the first and second electrode layers, the change in the polarization state of the ferroelectric layer causing the generation of a resultant electric field that extends from the ferroelectric layer into raised ring waveguide to modulate a refractive index of the non-centrosymmetric material

### BRIEF DESCRIPTION OF THE DRAWINGS

Various embodiments of the present disclosure are described below with reference to the following drawings:

FIG. 1 illustrates a perspective view of an electro-optic photonic memory device in accordance with an embodiment of the present disclosure;

FIG. 2 illustrates a perspective view of a FeFET and micro-ring resonator of the photonic memory device illustrated in FIG. 1 in accordance with an embodiment of the present disclosure;

FIG. 3 illustrates an exploded perspective view of the photonic memory device illustrated in FIG. 1 in accordance with an embodiment of the present disclosure;

FIG. 4 illustrates a cross-sectional view of a part of the photonic memory device across an x-y plane in accordance with embodiments of the present disclosure;

FIG. 5 illustrates a top view of the photonic memory device across an z-x plane in accordance with embodiments of the present disclosure;

FIG. 6 illustrates a perspective view of the photonic memory device with three FeFETs in accordance with embodiments of the present disclosure;

FIG. 7 illustrates high-resolution transmission electron microscope (HR-TEM) image of the photonic memory device in accordance with an embodiment of the present disclosure;

FIG. 8a illustrates a drain current versus applied gate voltage curve under forward and reverse gate bias conditions of the photonic memory device illustrated in FIG. 1;

FIG. 8b illustrates multiple non-volatile polarization-voltage loops of the photonic memory device illustrated in FIG. 1;

FIG. 8c illustrates shifts in micro-ring resonance transmission spectra in response to various states of the ferroelectric layer in the FeFET of the photonic memory device illustrated in FIG. 1;

FIG. 8d illustrates a cross-sectional view of the photonic memory device during a RESET operation and the corresponding band diagram of the photonic memory device when the device is in a volatile optical state;

FIG. 8e illustrates a cross-sectional view of the photonic memory device after a RESET operation and the corresponding band diagram of the photonic memory device when the device is in a reset optical state;

FIG. 8f illustrates a cross-sectional view of the photonic memory device during a WRITE operation and the corresponding band diagram of the photonic memory device when the device is in a non-volatile optical state;

FIG. 9 illustrates resonance shifts in the micro-ring resonator as a function of the number of applied consecutive pulses;

FIG. 10 illustrates the time dependence of three optical states observed over a period of 104 seconds after one-time write operation has been performed on the photonic memory device;

FIG. 11 illustrates the endurance performance of two optical states under specific pulse configurations; and

FIG. 12 illustrates a flowchart of a process to form a photonic memory device in accordance with an embodiment of the present disclosure.

### DETAILED DESCRIPTION

The following detailed description is made with reference to the accompanying drawings, showing details and embodiments of the present disclosure for the purposes of illustration. Features that are described in the context of an embodiment may correspondingly be applicable to the same or similar features in the other embodiments, even if not explicitly described in these other embodiments. Additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance as generally understood in the relevant technical field, e.g., within 10% of the specified value.

As used herein, the term “and/or” includes any and all combinations of one or more of the associated listed items.

As used herein, “comprising” means including, but not limited to, whatever follows the word “comprising”. Thus, use of the term “comprising” indicates that the listed elements are required or mandatory, but that other elements are optional and may or may not be present.

As used herein, “consisting of” means including, and limited to, whatever follows the phrase “consisting of”. Thus, use of the phrase “consisting of” indicates that the listed elements are required or mandatory, and that no other elements may be present.

As used herein, “disposed inward” means positioned or formed on a region (e.g., a region of a substrate or other supporting structure) that lies radially inward from a reference position, i.e., closer to a geometric center of a reference object. Conversely, as used herein, “disposed outward” means positioned or formed on a region that lies radially outward from a reference position, that is, farther from a geometric center of the reference object.

In the context of various embodiments, the term “surround” means to enclose something completely to form a barrier around it. Thus, the use of the term “surround” indicates that something is on all sides of another thing.

In the context of various embodiments, the term “disposed on” relates to the placement or deposition of one material or layer onto the surface of another and may involve one or more types of deposition techniques.

In the context of various embodiments, the term “around” or “adjacent” means to be in the proximity or location of something and does not necessarily mean that two objects have to be in contact.

In the context of various embodiments, the directional terms mentioned herein, such as “above” and “below” or “upper” and “lower” refer to directions as described with reference to the drawings. Therefore, the directional terms are only used for illustration and are not meant to limit the present disclosure.

It should be noted that although the terms first, second and third are used herein to describe various elements, these elements should not be limited by these terms as these terms are meant to only distinguish one element from another element. Thus, the first element described herein could be termed as a second element without departing from this disclosure.

As used herein, a “layer” refers to a material portion including a region having a particular thickness. The layer may extend over the entirety of the structure or may cover only part of the structure as defined in the description. For example, a layer may be located between two horizontal planes; may be located between, or at, a top surface and a bottom surface of the structure. The layer may also extend horizontally, vertically, and/or along the surface of the structure.

Additionally, for the sake of brevity, extensive explanations of conventional techniques of fabricating semiconductor devices and integrated circuits are not described in detail herein. The tasks and processes described herein may also be integrated into a more comprehensive procedure with extra steps of features that are not elaborated upon in this document. Specifically, certain processes of fabricating semiconductor devices are well known to one skilled in the art hence, such processes will be omitted entirely.

A typical electro-optic photonic memory device is a device that integrates electrical control with optical data storage and modulation. It stores information in an electrically programmable form while using light as the medium for reading, writing, or transmitting data. In such a device, an applied electrical signal alters the optical properties of a material, such as, but not limited to, its refractive index or phase through electro-optic effects, thereby encoding information into an optical mode confined within a photonic structure.

This disclosure describes an energy-efficient electro-optic photonic memory device, which combines low-field switchable ferroelectric materials with the strong Pockels effect of a non-centrosymmetric material, such as lithium niobate, to realize non-volatile, multi-state optical memory operation. In embodiments of the disclosure, the device integrates a Zr-doped Hafnium Zirconium Oxide (HZO) Ferroelectric Indium-Gallium-Zinc-Oxide (IGZO) field-effect transistor (FeFET) with a Lithium-Niobate-on-Insulator (LNOI) micro-ring resonator (MRR) to achieve direct and efficient electro-optic coupling.

By manipulating ferroelectric domain orientations within the HZO ferroelectric layer and exploiting the electro-optic response of the lithium niobate resonator, the device enables switchable, non-volatile optical memory states with multi-level storage capability (up to five distinct states) and an ultra-low energy consumption of 0.6 fJ per bit, while maintaining about 10-year retention and read-write endurance exceeding 10⁷ cycles. In further embodiments of the disclosure, multiple of such FeFETs may be co-integrated along the MRR to enable linear memory state stacking, thereby expanding logic and storage capacity while reducing the overall device count.

In short, the proposed electro-optic photonic memory provides not only a practical, multi-state non-volatile memory element with over 100× lower switching energy than existing approaches but also introduces a new energy-efficient pathway for non-volatile electro-optic wavelength tuning, achieving more than 100× reduction in tuning energy compared with conventional thermo-optic or other electro-optic methods.

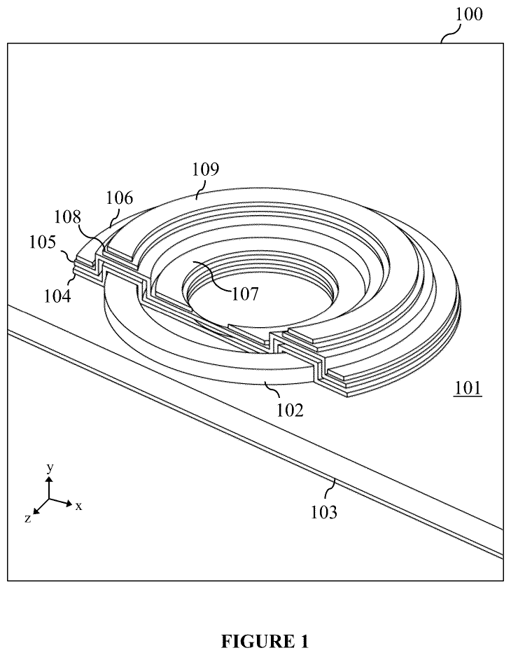

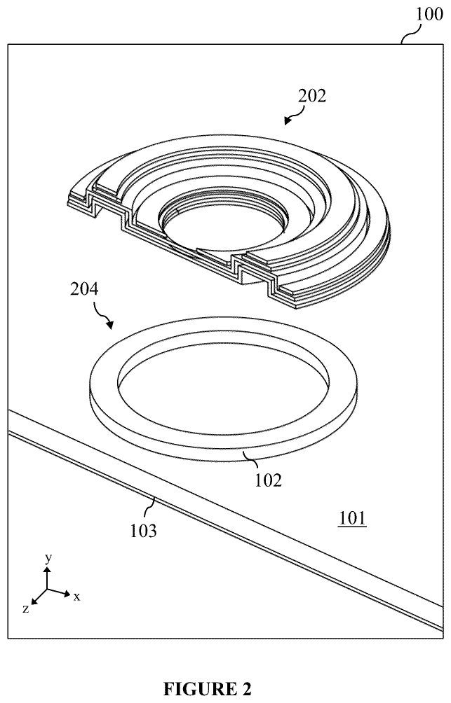

A perspective view of an electro-optic photonic memory device in accordance with an embodiment of the present disclosure is illustrated in FIG. 1 while a partially exploded perspective view of the electro-optic photonic memory device is illustrated in FIG. 2. As illustrated in FIGS. 1 and 2, electro-optic photonic memory device 100 (or photonic memory device 100) comprises micro-ring resonator 204 (see FIG. 2) and ferroelectric field effect transistor (FeFET) 202 (see FIG. 2) that is disposed along a partial circumference of a raised ring waveguide of micro-ring resonator 204. FeFET 202 is configured to be electrically programmable, enabling both volatile and non-volatile memory operation through polarization switching of the ferroelectric layer of FeFET 202.

As shown in these figures, micro-ring resonator 204 comprises raised ring waveguide 102 and bus waveguide 103 that are both disposed on substrate 101. Bus waveguide 103 is provided adjacent a part of an outer circumference of raised ring waveguide 102 such that optical signals may be coupled into and out of raised ring waveguide 102 via bus waveguide 103.

With reference to FIG. 1, it can be seen that FeFET 202 comprises channel layer 104 that is disposed on raised ring waveguide 102 such that channel layer 104 extends over a top surface of raised ring waveguide 102, over an inner portion of substrate 101 disposed inward of raised ring waveguide 102, and over an outer region of substrate 101 disposed outward of raised ring waveguide 102. Interfacial layer 105 is disposed on channel layer 104 and serves as a dielectric separation layer between channel layer 104 and the subsequently formed first and second electrodes 106, 107 respectively, and ferroelectric layer 108. The inner and outer regions of interfacial layer 105, which overlie the corresponding inner and outer regions of channel layer 104, support the formation of first electrode layer 106 and second electrode layer 107. In other words, it can be said that first electrode layer 106 is disposed on a portion of interfacial layer 105 such that first electrode layer 106 overlies channel layer 104 formed on the inner portion of substrate 101, and that second electrode layer 107 is disposed on interfacial layer 105 such that second electrode layer 107 overlies channel layer 104 formed on the outer portion of substrate 101.

As shown in FIG. 1, ferroelectric layer 108 is disposed on interfacial layer 105 such that ferroelectric layer 108 overlies a portion of channel layer 104 that is formed on the top surface of raised ring waveguide 102. Gate electrode 109 is subsequently disposed on ferroelectric layer 108. In operation, when a bias voltage is applied to gate electrode 109 and when first and second electrode layers 106 and 107 are electrically grounded, a polarization state of ferroelectric layer 108 changes. When the polarization state of ferroelectric layer 108 changes, this in turn causes the generation of a resultant electric field that extends from ferroelectric layer 108 into raised ring waveguide 102 to modulate a refractive index of the non-centrosymmetric material of raised ring waveguide 102 via the electro-optic (Pockels) effect.

It can be seen that FeFET 202 is only disposed on or only covers a partial circumference of raised ring waveguide 102 of micro-ring resonator 204. One skilled in the art will recognize that the extent to which FeFET 202 overlaps or covers raised ring waveguide 102 is not limited to the illustration in FIG. 1. In embodiments of the disclosure, FeFET 202 may cover almost the entire circumference of raised ring waveguide 102 except for the coupling area between raised ring waveguide 102 and bus waveguide 103.

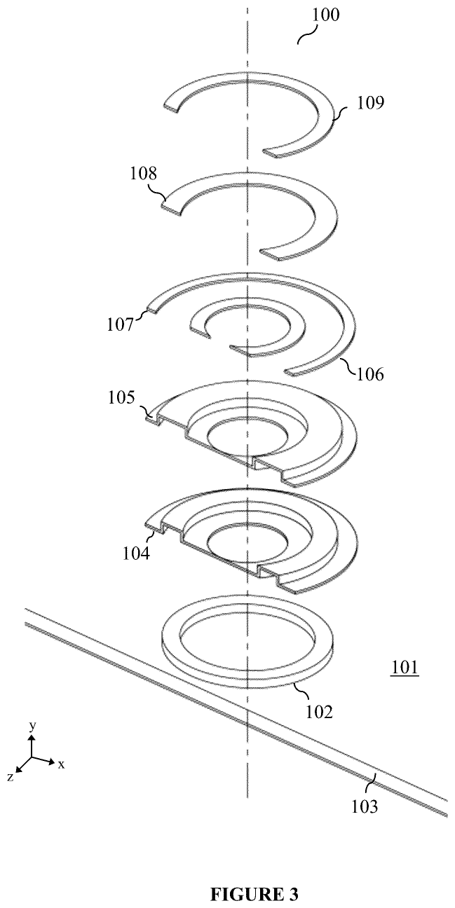

A more detailed exploded-view of FeFET 202 is illustrated in FIG. 3. As shown, the structural stack of FeFET 202 includes, from bottom to top, channel layer 104 that is disposed on raised ring waveguide 102, interfacial layer 105, first and second electrode layers 106 and 107 respectively, ferroelectric layer 108, and gate electrode 109. This exploded representation highlights the sequential and vertically aligned arrangement of the constituent layers, illustrating how channel layer 104 and overlying interfacial layer 105 conformally follow the curvature of raised ring waveguide 102. As can be seen, first and second electrode layers 106, 107 respectively are disposed at opposing sides of the curvature of raised ring waveguide 102 and serve as the source and drain terminals of the transistor. Ferroelectric layer 108 and gate electrode 109 together define the gate stack, which is positioned directly above the portion of the channel layer 104 overlying the top surface of the raised ring waveguide 102.

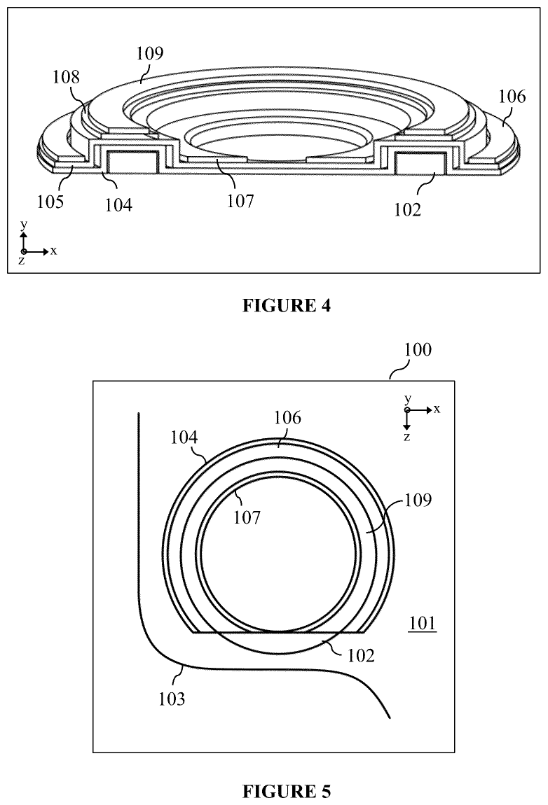

A cross-sectional view of photonic memory device 100 is illustrated in FIG. 4. As shown, the figure provides a clearer representation of the vertical layer arrangement and the structural relationship between the FeFET 202 and the underlying raised ring waveguide 102. This figure clearly shows first and second electrode layers 106 and 107 being disposed on laterally opposite sides of raised ring waveguide 102, while ferroelectric layer 108 and gate electrode 109 are sequentially stacked above the central portion of the device.

A top view of photonic memory device 100 is illustrated in FIG. 5. As shown, the figure depicts the spatial arrangement of FeFET 202 disposed along a partial circumference of the raised ring waveguide 102 that forms part of the micro-ring resonator. Channel layer 104 follows the curvature of raised ring waveguide 102, while first and second electrode layers 106 and 107 are positioned on opposing sides of the ring structure. Coupling waveguide 103 is located adjacent to the raised ring waveguide 102, allowing light propagating through coupling waveguide 103 to evanescently couple in and out of the ring.

In embodiments of the disclosure, it can be said that FeFET 202 comprises a metal-ferroelectric gate stack (i.e., gate electrode 109 formed on ferroelectric layer 108) formed on a heterojunction-engineered oxide semiconductor channel layer (i.e., interfacial layer 105 formed on channel layer 104). In embodiments, ferroelectric layer 108 may comprise but is not limited to materials such as Hafnium Zirconium Oxide (HZO), Barium Titanate, or Lead Zirconate Titanate while gate electrode 109 may comprise a bulk conductive Indium Tin Oxide (ITO) material. Interfacial layer 105 may comprise a material such as Oxygen-rich Indium Tin Oxide (ITOₓ) and channel layer 104 may comprise a material such as Indium Gallium Zinc Oxide (IGZO). The use of an oxide semiconductor channel, in contrast to conventional silicon-based FeFETs, is advantageous due to its ultra-low leakage current, low refractive index (n_{IGZO}=1.7 as compared to n_{Si}=3.5), and low thermal processing requirement (maximum temperature below 400° C.) while maintaining compatibility with standard CMOS interconnect metallization processes. Additionally, the non-centrosymmetric material of raised ring waveguide 102 may comprise Lithium Niobate, Potassium Dihydrogen Phosphate, Gallium Arsenide or Barium Titanate.

It should be noted that the metal-ferroelectric gate stack and heterojunction channel layer are engineered for high reliability and non-volatile memory performance, benefiting from a defect self-compensation effect achieved by incorporating interfacial layer 105 that passivates intrinsic interface and bulk defects within channel layer 104.

In embodiments of the disclosure, the materials chosen for FeFET 202 may comprise materials having the following refractive indexes where IGZO has a refractive index of n_{IGZO}=1.7, HZO has a refractive index of n_{HZO}=1.9, and ITO has a refractive index of n_{ITO}=1.5 that are all lower than Lithium Niobate's refractive index of n₂=2.2 in the C-band infrared region (wavelength range: 1530-1565 nm). This contrast in the respective optical indexes serves to minimize light out-coupling losses from the underlying waveguide while preserving efficient confinement of the guided optical mode within the non-centrosymmetric lithium niobate material.

When in use, the wavelength-dependent resonances of micro-ring resonator 204 may vary in response to the polarization switching of ferroelectric layer 108 of FeFET 202. This polarization switching may be induced by applying a bias voltage to gate electrode 109, while maintaining the first and second electrodes 106 and 107 at ground potential. When this happens, the applied gate bias establishes an electric field across ferroelectric layer 108, reorienting its dipole polarization and thereby altering the resultant electric field penetrating into the underlying raised ring waveguide 102. This modulation of the internal electric field changes the refractive index of the non-centrosymmetric material of raised ring waveguide 102 via the Pockels effect, resulting in a measurable shift in the optical resonance wavelength of the MRR.

In addition to optical interrogation, the memory states of photonic memory device 100 can also be electrically read by measuring the channel current conducted through channel layer 104 between first and second electrodes 106, 107 when these electrodes are designated as the drain/source or source/drain electrodes, respectively. The measured current between these electrodes vary (when a small voltage difference is applied between these electrodes) with the polarization state of ferroelectric layer 108, enabling independent electrical verification of the stored optical memory state through FeFET 202's current-voltage characteristics. In operation, photonic memory device 100 permits the polarization of ferroelectric layer 108 to be switched when an electrical signal is applied at gate electrode 109, which in turn induces a corresponding shift in the optical resonance wavelength of raised ring waveguide 102. Consequently, the memory state of photonic memory device 100 may be assessed through either optical means, by monitoring changes in resonance behavior, or electrical means, by evaluating the transistor's channel current response, thereby providing dual-mode electrical/optical memory readout functionality.

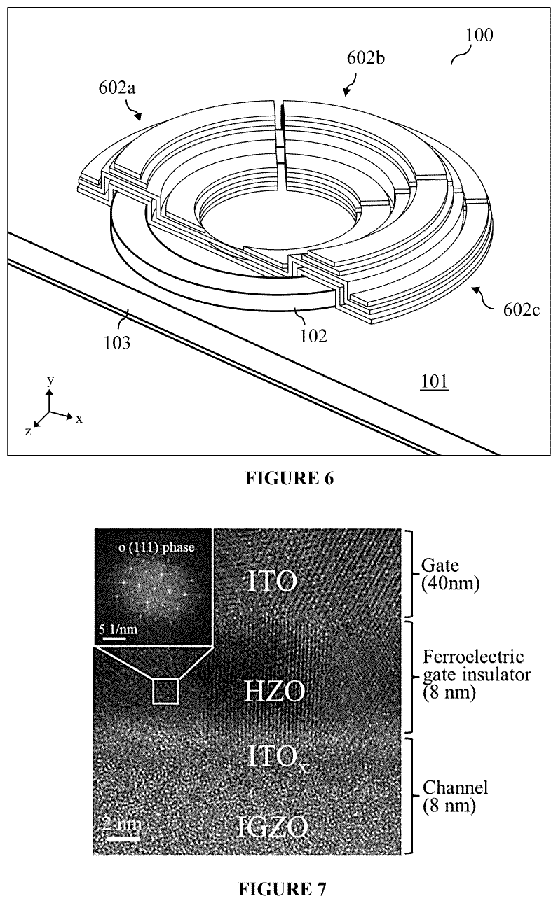

A perspective view of another embodiment of photonic memory device 100 is illustrated in FIG. 6. As shown, this embodiment includes a plurality of FeFETs 602a, 602b, and 602c, each disposed along different circumferential sections of raised ring waveguide 102 of the micro-ring resonator. Each FeFET is structurally similar to FeFET 202 described in the previous embodiments and each of these FeFETs 602a, 602b and 602c is independently addressable by applying a corresponding bias voltage to its respective gate electrode.

One skilled in the art will recognize that the number of FeFETs disposed along different circumferential sections of raised ring waveguide 102 is not limited to three, as illustrated in FIG. 6, and that any number of such FeFETs may be employed depending on the desired degree of electro-optic modulation or memory capacity. Furthermore, the thickness, geometry, and material composition of each FeFET may be varied independently to achieve tailored electrical or optical responses. For example, the ferroelectric layer, semiconductor channel, or electrode materials of each FeFET may be selected to optimize polarization strength, switching voltage, or optical coupling efficiency for its specific position along the ring. Accordingly, the present disclosure is not limited to uniform FeFET configurations, but rather encompasses implementations wherein individual FeFETs differ in layer thicknesses, material compositions, or electrical characteristics while remaining functionally coupled to the same raised ring waveguide 102.

The placement of multiple FeFETs around the ring waveguide allows each device to induce a localized modulation of the electric field penetrating into the underlying non-centrosymmetric material of the raised ring waveguide 102. The cumulative effect of these localized modulations results in an overall change in the effective refractive index of the ring waveguide, thereby enabling scalable and finely tunable electro-optic control of the resonance characteristics of the micro-ring resonator. Through independent electrical addressing of each FeFET 602a-602c, multiple optical states can be linearly combined or “stacked,” enhancing the dynamic range of the photonic memory device while reducing the total number of discrete device elements required to achieve multi-level memory functionality.

FIG. 7 illustrates a high-resolution transmission electron microscopy (HR-TEM) image of photonic memory device 100, showing the detailed layer structure formed above the raised ring waveguide 102. The thickness and stacking order of the constituent layers are indicated as follows (from bottom to top): 5 nm IGZO channel layer, 3 nm ITOₓ interfacial layer, 8 nm HZO ferroelectric gate insulator, and 40 nm ITO gate electrode. Each layer is clearly distinguishable, confirming the high-quality interfaces between the semiconductor, ferroelectric, and electrode materials. For completeness, a Fast Fourier Transform (FFT) diffraction pattern corresponding to the HZO ferroelectric layer is inserted in the inset, showing the characteristic diffraction spots of the orthorhombic (o-phase) structure, which is responsible for the observed ferroelectric behavior. Specifically, the HZO ferroelectric layer exhibits a polar o-phase crystal structure, which is known to produce the strongest ferroelectric behavior in polycrystalline HZO films. The polarization of the individual ferroelectric domains within the HZO ferroelectric layer is oriented along the longitudinal (z) direction of the device structure, corresponding to the vertical electric field across the ferroelectric stack. This polarization alignment is achieved by ensuring that the electric field applied through the HZO ferroelectric layer is directed along the z-axis. Such alignment is particularly advantageous because z-cut Lithium Niobate (LN) exhibits its highest Pockels electro-optic coefficient (r₃₃=32 pm/V) along the same axis, enabling efficient electro-optic modulation and enhanced power efficiency. Furthermore, as shown in FIG. 7, the HZO ferroelectric layer interfaces with the LN material of the raised ring waveguide through the ultra-thin IGZO transistor body (approximately 8 nm thick), thereby facilitating strong coupling between the ferroelectric polarization of the HZO and the electro-optic response of the raised ring waveguide.

### Operation of the Photonic Memory Device

As a result of its non-centrosymmetric crystal structure, LN inherently exhibits a spontaneous ferroelectric polarization (PLN) arising from the separation of positive (Nb⁺) and negative (LiO₃⁻) charge centers within the lattice. Due to this intrinsic ferroelectric property, dipole interactions naturally occur between the ferroelectric domains of the HZO ferroelectric layer and those of the LN layer. The dipole charge density of LN has been reported to be approximately 70 μC/cm², which is about 4.4 times greater than the typical polarization magnitude of HZO, indicating that the LN layer exerts a dominant electrostatic influence within the device stack. Furthermore, to effectively guide optical modes within the micro-ring resonator, the LN layer, i.e., the raised ring waveguide layer, is formed with a significantly greater thickness (approximately 0.6 μm) compared to the thin-film transistor stack and the HZO ferroelectric layer. Consequently, the polarization state of LN substantially affects the electric field distribution and field-effect behaviour of the FeFET structure. These coupled interactions establish an electrostatic balance between the dipole fields of HZO and LN, in conjunction with the gate-induced charge modulation within the channel layer, collectively determining the operation, programming, and erasing characteristics of the photonic memory device.

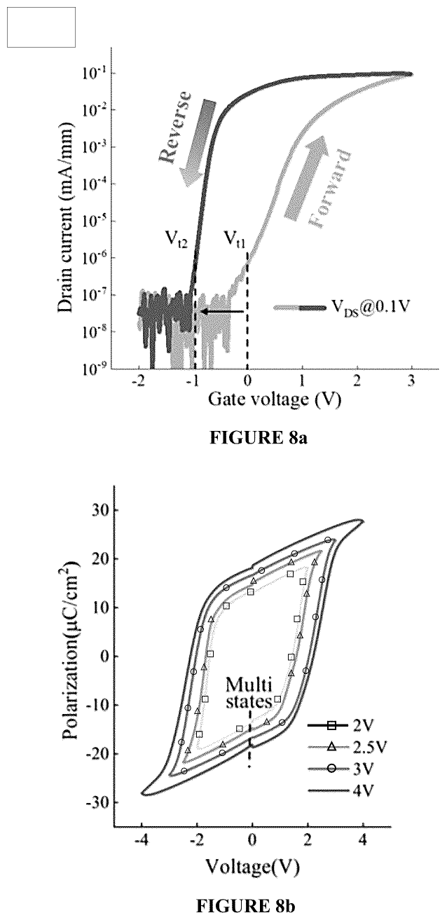

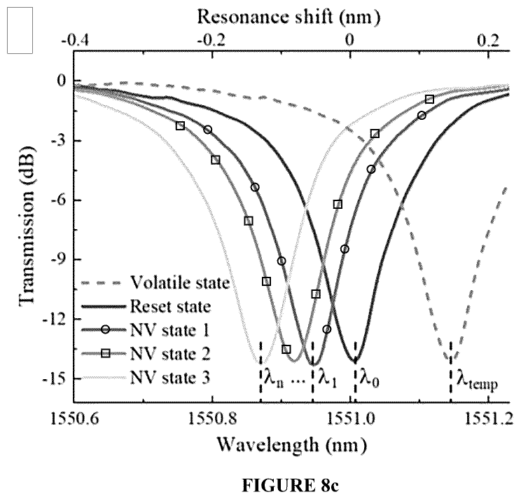

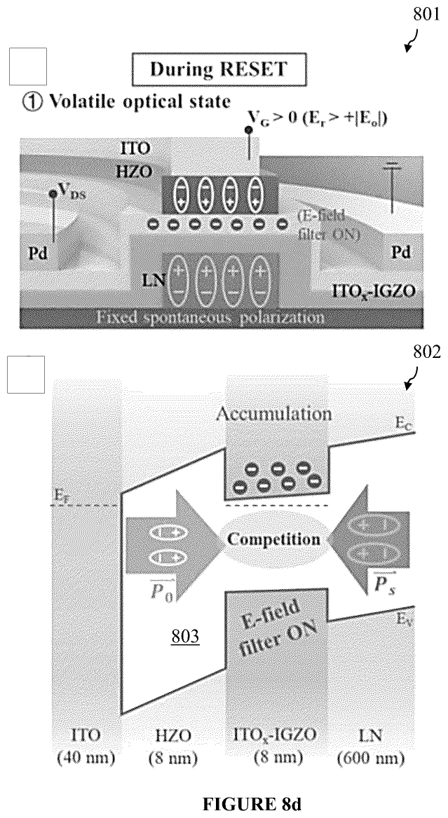

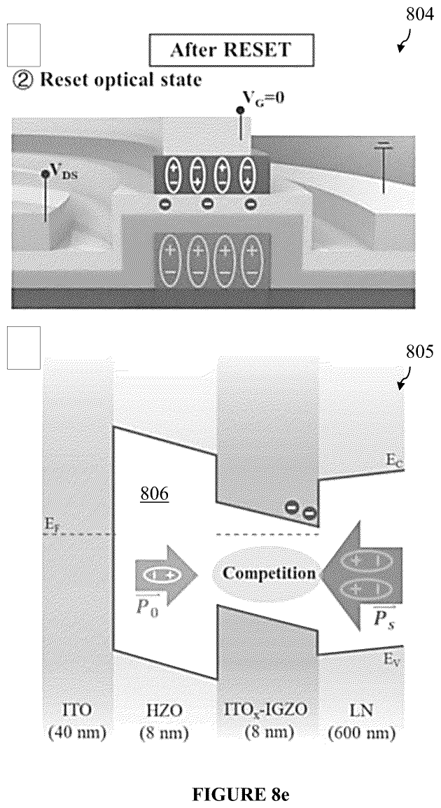

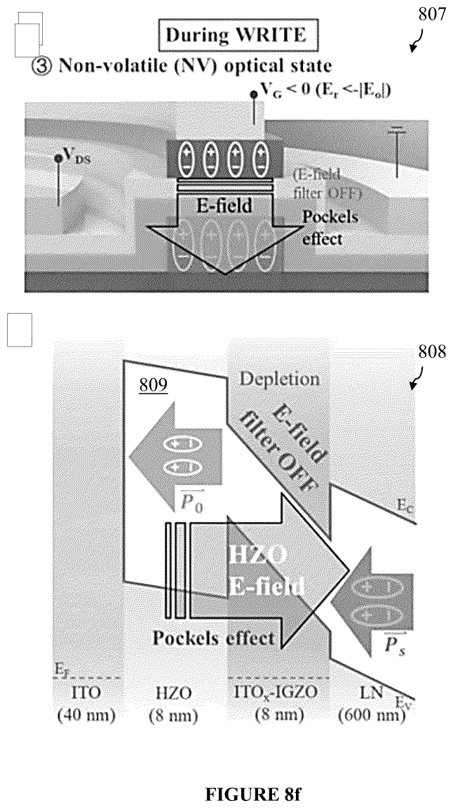

As illustrated in FIG. 8a, the polarization state of the HZO ferroelectric layer can be reversed by applying a gate voltage pulse (V_{G}) through the top gate electrode, thereby generating an electric field (Eᵣ) that exceeds the coercive field magnitude (±|E₀|) of the ferroelectric material. When this threshold is surpassed, the ferroelectric dipoles within the HZO ferroelectric layer realign in response to the polarity of the applied electric field. The resulting change in dipole orientation modifies the threshold voltage (V₁) of the FeFET, producing a measurable shift in the transistor's turn-on behavior. Depending on the magnitude and direction of the induced ferroelectric polarization, the device exhibits either an accumulation state (characterized by high channel conductivity) or a depletion state (characterized by low channel conductivity) even when no external gate voltage is applied. This polarization-controlled modulation of channel conductivity enables the non-volatile storage of distinct memory states in the photonic memory device.

When the applied electric field across the HZO ferroelectric layer decreases below its coercive field threshold, the ferroelectric dipoles remain stable in their previously switched orientation, thereby retaining the programmed polarization state. The remnant polarization of the HZO ferroelectric layer induces a redistribution of electrons within the channel layer, where the degree of electron accumulation determines the extent of electrostatic screening of the polarization charges associated with the ferroelectric dipoles. This screening effect regulates the magnitude of the electric field penetrating from the ferroelectric layer through the transistor body into the underlying LN micro-ring resonator. The transistor body thus functions as an electric-field filter, with the channel charge density controlling how much of the electric field is transmitted into the LN layer.

The resultant electric field emerging from the transistor body modulates the refractive index of the LN layer through the Pockels effect, producing a corresponding phase shift in the optical mode circulating within the micro-ring resonator. This phase shift alters the optical path length difference (OPD) of the resonator, which can be expressed as:

$$OPD = 2 π {rn}_{eff} = ( m + \frac{1}{2} ) λ$$

where r is the radius of the ring resonator, n_{eff} is the effective refractive index of the waveguide material, λ is the resonant wavelength, and m is the mode number of the raised ring resonator. Variations in the transmitted electric field, and consequently in the effective refractive index, give rise to measurable resonance wavelength shifts in the micro-ring resonator, as illustrated in FIG. 8c.

In embodiments of the disclosure, the memory operation of the photonic memory device 100 is governed by two principal processes, the RESET operation and the WRITE operation. It is also further associated with three distinct memory states: volatile, reset, and non-volatile. Prior to initiating the WRITE process to establish a stable non-volatile memory state, a RESET operation is performed. During the RESET operation, a positive gate bias voltage (V_{G}) is applied to the gate electrode, generating an electric field across the HZO ferroelectric layer that exceeds its coercive field. This applied electric field forces the polarization of the HZO dipoles to align in a direction opposite to the spontaneous polarization of the LN layer, i.e., the raised ring waveguide.

Simultaneously, the positive gate bias induces a significant accumulation of electrons within the IGZO channel layer, as illustrated in images 801 and 802 of FIG. 8d. Specifically, image 801 illustrates a cross-section illustration of the photonic memory during the RESET operation while image 802 illustrates the band diagrams along the vertical stack of the device when the device is in a volatile optical state, whereby region 803 represents the energy gap of the band diagram.

The accumulated electrons not only screen the applied gate field, but also shield the HZO dipoles from the opposing field generated by the LN polarization. Under these conditions, the electric field (E_{LN}) at the LN interface remains directed downward (i.e., E_{LN}>0), maintaining an electrostatic orientation that temporarily stabilizes the volatile polarization configuration. As a result, the optical resonance of the micro-ring resonator is positioned at a temporary wavelength (λₜₑₘₚ), as shown in FIG. 8c. It should be noted that this volatile state is temporary and persists only while the gate bias is applied. In other words, the device reverts upon removal of the voltage, thereby defining the RESET condition of the photonic memory device.

Upon removal of the positive gate bias (V_{G}), the previously accumulated electrons within the IGZO channel layer dissipate, leading to a reduction in the channel's electrostatic screening capability. As a result, the HZO ferroelectric layer undergoes partial depolarization, retaining approximately one-sixth of its original polarization. This partial depolarization arises from the dominant opposing electric field generated by the strongly polarized LN layer, whose spontaneous polarization is approximately 4.4 times greater than that of HZO. Under these conditions, the device stabilizes into the RESET state, as illustrated in images 804 and 805 of FIG. 8e. Specifically, image 804 illustrates a cross-section illustration of the photonic memory during the after-RESET operation while image 805 illustrates the band diagrams along the vertical stack of the device when the device is in a reset optical state, whereby region 806 represents the energy gap of the band diagram.

During this transition state, the electric field (E_{LN}) at the LN interface reverses direction, becoming upward-oriented (i.e., E_{LN}<0). This change in field polarity induces a Pockels effect in the LN layer, thereby modifying its refractive index and shifting the optical resonance of the micro-ring resonator to the baseline wavelength (Ao), as depicted in FIG. 8c. The RESET state thus represents a stable electro-optic equilibrium between the residual polarization of the HZO ferroelectric layer and the spontaneous polarization of the LN layer, establishing the reference optical state of the photonic memory device.

The WRITE operation of photonic memory device is subsequently carried out by applying a negative gate bias voltage (V_{G}) to the gate electrode of the FeFET. This applied bias generates an electric field across the HZO ferroelectric layer that exceeds its coercive field, thereby inducing a reversal and alignment of ferroelectric dipoles in the direction consistent with the spontaneous polarization of the LN layer, i.e., the raised ring waveguide. The magnitude of HZO polarization can be precisely controlled by adjusting the amplitude and number of WRITE pulses, enabling the device to store multiple discrete polarization levels corresponding to distinct optical memory states, as illustrated in FIG. 8b.

Once the desired WRITE pulses are applied, the HZO ferroelectric states remain non-volatile and stable even after the removal of the gate bias, retaining the stored polarization until a subsequent RESET operation is executed. Following removal of the WRITE bias, the electric field (E_{LN}) at the LN interface remains upward-directed (i.e., E_{LN}<0) and its magnitude is determined by the strength of the remnant HZO polarization, as shown in images 807 and 808 of FIG. 8f. Specifically, image 807 illustrates a cross-section illustration of the photonic memory during the WRITE operation while image 808 illustrates the band diagrams along the vertical stack of the device when the device is in a non-volatile optical state, whereby region 809 represents the energy gap of the band diagram. This sustained field induces a Pockels-driven modulation of the refractive index of the LN layer, resulting in a leftward resonance shift of the micro-ring resonator from λ₀ to a new wavelength λₙ (λₙ<λ₀).

It should be noted that each distinct ferroelectric polarization level in the HZO ferroelectric layer corresponds to a unique non-volatile optical memory state, forming a set of stable, discretely spaced resonance positions in the optical spectrum, as shown in FIG. 8c. Moreover, these ferroelectric states can be electrically verified by monitoring threshold voltage shifts of the FeFET, providing a bimodal readout mechanism that allows both electrical and optical interrogation of the stored memory state. Because the HZO dipole orientation aligns with the LN spontaneous polarization, the ferroelectric polarization is strongly stabilized, resulting in excellent state retention and long-term non-volatility of the optical memory device.

### Experimental Results

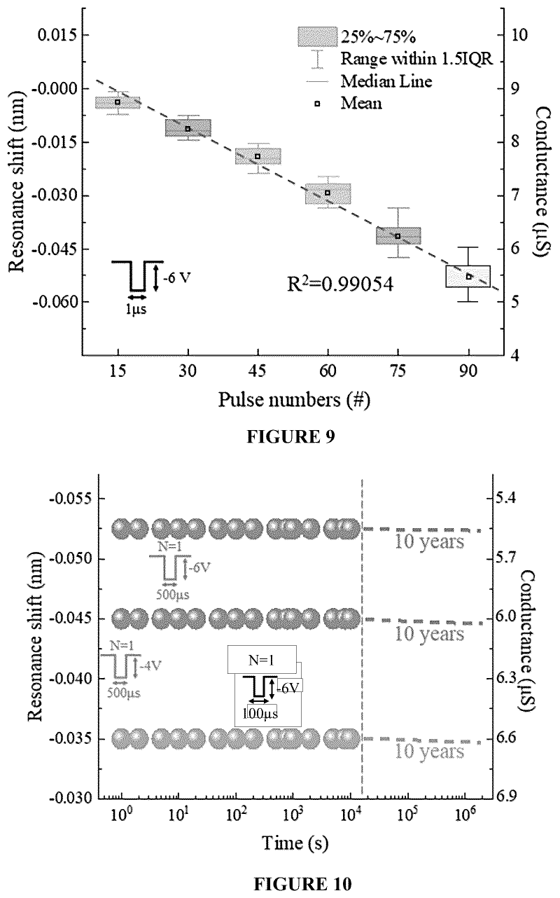

To evaluate the multi-state memory characteristics of the photonic memory device designed in accordance with embodiments of the disclosure, the device was first initialized to a baseline condition referred to as state ‘0’, after which a sequence of identical negative WRITE pulses (1 μs duration, −6 Volt amplitude) was applied to the gate electrode. By incrementally increasing the number of applied WRITE pulses, the degree of polarization within the HZO ferroelectric layer was progressively strengthened, thereby generating six discrete and stable resonance states, as illustrated in FIG. 9. The box plots in this figure illustrate the variation of each state under a 50-time pulse configuration operation. Hence, it can be observed that each of these resonance states corresponds to a distinct level of ferroelectric polarization and, consequently, a unique optical resonance wavelength in the micro-ring resonator.

Statistical validation of these six states was conducted through 50 repeated write-read cycles for each condition, demonstrating excellent reproducibility and minimal state overlap. The experimental data revealed a linear correlation between the number of applied WRITE pulses and the resultant optical resonance shift, confirming precise and predictable multi-level control of the memory states.

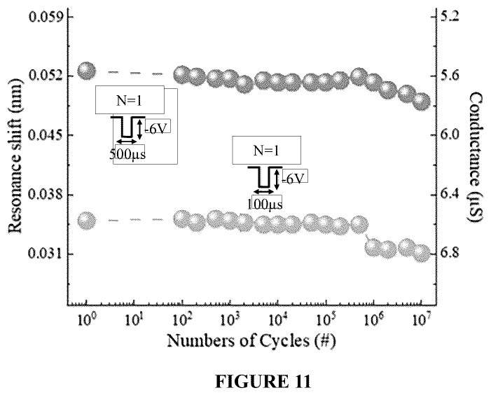

Furthermore, to assess temporal stability and data retention, three representative memory states written using different pulse counts were continuously monitored over a three-hour observation period, as shown in FIG. 10. It should be noted that the specific pulse configurations applied during this period are represented in this figure. The recorded resonance wavelengths exhibited negligible drift during this interval, allowing extrapolation through a retention model that predicts an estimated memory lifetime of approximately 10 years. These results affirm that the device exhibits robust non-volatility, multi-level programmability, and long-term stability, essential for practical implementation in photonic in-memory computing and reconfigurable optical systems.

It is well recognized that ferroelectric materials are prone to polarization fatigue, wherein repetitive switching of dipole orientation may lead to gradual degradation of ferroelectric performance over extended operation. To evaluate the endurance and reliability of the photonic memory device, a comprehensive WRITE/RESET cycling test was performed, with the results summarized in FIG. 11. Across these cycles, the resonance window of the micro-ring resonator remained consistent, indicating minimal degradation in ferroelectric behaviour. When the cycling was extended to 10⁷ cycles, only a slight reduction in the resonance shift amplitude was observed. This minor change is attributed to limited ferroelectric fatigue effects within the HZO ferroelectric layer, which may arise from localized dipole pinning or interface charge trapping during prolonged operation.

Nevertheless, the device maintained functional stability and repeatable optical response even after extensive cycling, confirming that the HZO-LN heterostructure provides excellent fatigue resistance and endurance suitable for long-term non-volatile photonic memory applications. These findings reinforce the reliability of the integrated FeFET-MRR platform for use in high-speed, reconfigurable photonic systems requiring repeated programming and erasure over extended lifetimes.

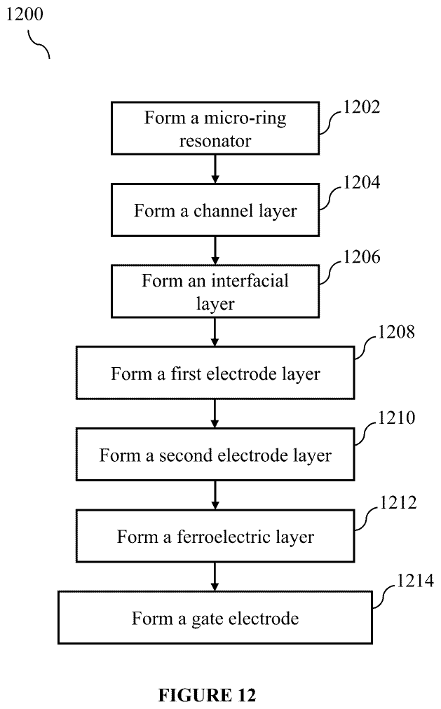

A process for forming an electro-optic photonic memory device in accordance with embodiments of the disclosure is illustrated in FIG. 12. It should be noted that process 1200 may be performed using standard semiconductor fabrication or manufacturing steps. At step 1202, a micro-ring resonator including a raised ring waveguide is initially formed on a substrate, wherein the raised ring waveguide comprises a non-centrosymmetric material. A ferroelectric field effect transistor (FeFET) is subsequently formed by process 1200 along a partial circumference of the raised ring waveguide of the micro-ring resonator. The process of forming the FeFET by process 1200 may be described in more detail by steps 1204-1214.

Specifically, at step 1204, a channel layer is formed on the raised ring waveguide such that the channel layer extends over a top surface of the raised ring waveguide, over an inner portion of the substrate disposed inward of the raised ring waveguide, and over an outer region of the substrate disposed outward of the raised ring waveguide. Process 1200 then forms an interfacial layer on the channel layer at step 1206. Then, at step 1208, process 1200 subsequently forms a first electrode layer on the interfacial layer such that the first electrode layer overlies the channel layer formed on the inner portion of the substrate. At step 1210, process 1200 forms a second electrode layer on the interfacial layer such that the second electrode layer overlies the channel layer formed on the outer portion of the substrate. A ferroelectric layer is then formed on the interfacial layer such that the ferroelectric layer overlies the channel layer formed on the top surface of the raised ring waveguide. This takes place at step 1212. Process 1200 then forms a gate electrode on the ferroelectric layer at step 1214.

After the gate electrode has been formed, a polarization state of the ferroelectric layer may be changed applying a bias voltage to the gate electrode and electrically grounding the first and second electrode layers, the change in the polarization state of the ferroelectric layer causing the generation of a resultant electric field that extends from the ferroelectric layer into the raised ring waveguide to modulate a refractive index of the non-centrosymmetric material.

In embodiments of the disclosure, the bias voltage may comprise a positive voltage that causes ferroelectric dipoles of the ferroelectric layer to align in a direction opposite to a spontaneous polarization of the non-centrosymmetric material, causing the resultant electric field to extend in a downward direction from the ferroelectric layer into the raised ring waveguide. Upon removal of the positive voltage, the ferroelectric layer then partially depolarizes due to the resultant electric field extending in an upward direction from the raised ring waveguide to the ferroelectric layer, the resultant electric field reducing a magnitude of remanent polarization of the ferroelectric layer while maintaining a same polarization direction.

In embodiments of the disclosure, the bias voltage may comprise a negative voltage that causes ferroelectric dipoles of the ferroelectric layer to align in a direction aligned with a spontaneous polarization of the non-centrosymmetric material, causing the resultant electric field to extend in an upward direction from the raised ring waveguide to the ferroelectric layer.

In embodiments of the disclosure, a stored memory state of the photonic memory device may be determined by optically interrogating a resonance wavelength of the micro-ring resonator using an input optical signal coupled into the raised ring waveguide or it may be determined by measuring a channel current through the channel layer in response to a source-drain voltage applied between the first and second electrode layers, the channel current being modulated by the polarization state of the ferroelectric layer.

In embodiments of the disclosure, a plurality of the FeFETs may be formed along different circumferential sections of the raised ring waveguide, wherein each of the plurality of FeFETs is independently addressable by applying a corresponding bias voltage to the gate electrode of the FeFET to cumulatively modulate the refractive index of the non-centrosymmetric material.

Numerous other changes, substitutions, variations, and modifications may be ascertained by the skilled in the art and it is intended that the present application encompass all such changes, substitutions, variations and modifications as falling within the scope of the appended claims.

1. An electro-optic photonic memory device comprising:
a micro-ring resonator including a raised ring waveguide formed on a substrate, wherein the raised ring waveguide comprises a non-centrosymmetric material;
a ferroelectric field effect transistor (FeFET) disposed along a partial circumference of the raised ring waveguide of the micro-ring resonator, the FeFET comprising:
a channel layer disposed on the raised ring waveguide such that the channel layer extends over a top surface of the raised ring waveguide, over an inner portion of the substrate disposed inward of the raised ring waveguide, and over an outer region of the substrate disposed outward of the raised ring waveguide;
an interfacial layer disposed on the channel layer;
a first electrode layer disposed on the interfacial layer such that the first electrode layer overlies the channel layer formed on the inner portion of the substrate;
a second electrode layer disposed on the interfacial layer such that the second electrode layer overlies the channel layer formed on the outer portion of the substrate;
a ferroelectric layer disposed on the interfacial layer such that the ferroelectric layer overlies the channel layer formed on the top surface of the raised ring waveguide; and
a gate electrode disposed on the ferroelectric layer,
wherein a polarization state of the ferroelectric layer changes in response to a bias voltage being applied to the gate electrode and the first and second electrode layers being electrically grounded, the change in the polarization state of the ferroelectric layer causing the generation of a resultant electric field that extends from the ferroelectric layer into the raised ring waveguide to modulate a refractive index of the non-centrosymmetric material.

2. The photonic memory device according to claim 1,
wherein the bias voltage comprises a positive voltage that causes ferroelectric dipoles of the ferroelectric layer to align in a direction opposite to a spontaneous polarization of the non-centrosymmetric material, causing the resultant electric field to extend in a downward direction from the ferroelectric layer into the raised ring waveguide.

3. The photonic memory device according to claim 2,
wherein upon removal of the positive voltage, the ferroelectric layer partially depolarizes due to the resultant electric field extending in an upward direction from the raised ring waveguide to the ferroelectric layer, the resultant electric field reducing a magnitude of remanent polarization of the ferroelectric layer while maintaining a same polarization direction.

4. The photonic memory device according to claim 1,
wherein the bias voltage comprises a negative voltage that causes ferroelectric dipoles of the ferroelectric layer to align in a direction aligned with a spontaneous polarization of the non-centrosymmetric material, causing the resultant electric field to extend in an upward direction from the raised ring waveguide to the ferroelectric layer.

5. The photonic memory device according to claim 1,
wherein a stored memory state of the photonic memory device is determined by optically interrogating a resonance wavelength of the micro-ring resonator using an input optical signal coupled into the raised ring waveguide.

6. The photonic memory device according to claim 1,
wherein a stored memory state of the photonic memory device is determined by measuring a channel current through the channel layer in response to a source-drain voltage applied between the first and second electrode layers, the channel current being modulated by the polarization state of the ferroelectric layer.

7. The photonic memory device according to claim 1,
wherein the non-centrosymmetric material comprises Lithium Niobate, Potassium Dihydrogen Phosphate, Gallium Arsenide or Barium Titanate.

8. The photonic memory device according to claim 1,
wherein the ferroelectric layer comprises Hafnium Zirconium Oxide, Barium Titanate, or Lead Zirconate Titanate.

9. The photonic memory device according to claim 1, wherein the channel layer comprises Indium Gallium Zinc Oxide.

10. The photonic memory device according to claim 1, wherein the interfacial layer comprises Indium Tin Oxide.

11. The photonic memory device according to claim 1, further comprising:
a plurality of the FeFETs disposed along different circumferential sections of the raised ring waveguide, wherein each of the plurality of FeFETs is independently addressable by applying a corresponding bias voltage to the gate electrode of the FeFET to cumulatively modulate the refractive index of the non-centrosymmetric material.

12. A method for forming an electro-optic photonic memory device comprising:
forming a micro-ring resonator including a raised ring waveguide formed on a substrate, wherein the raised ring waveguide comprises a non-centrosymmetric material;
forming a ferroelectric field effect transistor (FeFET) along a partial circumference of the raised ring waveguide of the micro-ring resonator comprising the steps of:
forming a channel layer on the raised ring waveguide such that the channel layer extends over a top surface of the raised ring waveguide, over an inner portion of the substrate disposed inward of the raised ring waveguide, and over an outer region of the substrate disposed outward of the raised ring waveguide;
forming an interfacial layer on the channel layer;
forming a first electrode layer on the interfacial layer such that the first electrode layer overlies the channel layer formed on the inner portion of the substrate;
forming a second electrode layer on the interfacial layer such that the second electrode layer overlies the channel layer formed on the outer portion of the substrate;
forming a ferroelectric layer on the interfacial layer such that the ferroelectric layer overlies the channel layer formed on the top surface of the raised ring waveguide; and
forming a gate electrode on the ferroelectric layer,
wherein a polarization state of the ferroelectric layer is changed by applying a bias voltage to the gate electrode and electrically grounding the first and second electrode layers, the change in the polarization state of the ferroelectric layer causing the generation of a resultant electric field that extends from the ferroelectric layer into the raised ring waveguide to modulate a refractive index of the non-centrosymmetric material.

13. The method according to claim 12,
wherein the bias voltage comprises a positive voltage that causes ferroelectric dipoles of the ferroelectric layer to align in a direction opposite to a spontaneous polarization of the non-centrosymmetric material, causing the resultant electric field to extend in a downward direction from the ferroelectric layer into the raised ring waveguide.

14. The method according to claim 13,
wherein upon removal of the positive voltage, the ferroelectric layer partially depolarizes due to the resultant electric field extending in an upward direction from the raised ring waveguide to the ferroelectric layer, the resultant electric field reducing a magnitude of remanent polarization of the ferroelectric layer while maintaining a same polarization direction.

15. The method according to claim 12,
wherein the bias voltage comprises a negative voltage that causes ferroelectric dipoles of the ferroelectric layer to align in a direction aligned with a spontaneous polarization of the non-centrosymmetric material, causing the resultant electric field to extend in an upward direction from the raised ring waveguide to the ferroelectric layer.

16. The method according to claim 12, further comprising the step of:
determining a stored memory state of the photonic memory device by optically interrogating a resonance wavelength of the micro-ring resonator using an input optical signal coupled into the raised ring waveguide.

17. The method according to claim 12, further comprising the step of:
determining a stored memory state of the photonic memory device by measuring a channel current through the channel layer in response to a source-drain voltage applied between the first and second electrode layers, the channel current being modulated by the polarization state of the ferroelectric layer.

18. The method according to claim 12,
wherein the non-centrosymmetric material comprises Lithium Niobate, Potassium Dihydrogen Phosphate, Gallium Arsenide or Barium Titanate,
the ferroelectric layer comprises Hafnium Zirconium Oxide, Barium Titanate, or Lead Zirconate Titanate,
the channel layer comprises Indium Gallium Zinc Oxide, and
the interfacial layer comprises Indium Tin Oxide.

19. The method according to claim 12, further comprising the step of:
forming a plurality of the FeFETs along different circumferential sections of the raised ring waveguide, wherein each of the plurality of FeFETs is independently addressable by applying a corresponding bias voltage to the gate electrode of the FeFET to cumulatively modulate the refractive index of the non-centrosymmetric material.
